(19) United States
(12) Patent Application Publication
(10) Pub. No.: US 2007/0007639 A1
(43) Pub. Date: Jan. 11, 2007

(54) Semiconductor device, manufacturing method for semiconductor device, and electronic equipment

(76) Inventor: Motohiko Fukazawa, Toyota-shi (JP)

Correspondence Address: HARNESS, DICKEY & PIERCE, P.L.C., P.O. BOX 828, BLOOMFIELD HILLS, MI, 48303, US

(21) Appl. No.: 11/473,523

(22) Filed: Jun. 22, 2006

(30) Foreign Application Priority Data
Jun. 24, 2005 (JP) 2005-184651
Mar. 6, 2006 (JP) 2006-059963

(51) Int. Cl. H01L 23/02; H01L 21/00

(52) U.S. Cl. 257/686; 438/109; 257/E23.085

(57) ABSTRACT

A semiconductor device includes: a plurality of stacked semiconductor chips including a first semiconductor chip having a side surface, and a second semiconductor chip stacked on the first semiconductor chip; and a sealing resin placed between the plurality of semiconductor chips, at least one edge of the first semiconductor chip is positioned on an inner side of the second semiconductor chip, and the sealing resin placed between the first semiconductor chip and the second semiconductor chip is extended over the side surface of the first semiconductor chip.

### CROSS-REFERENCE TO RELATED APPLICATION

This application claims priority from Japanese Patent Application No. 2005-184651, filed Jun. 24, 2005, and Japanese Patent Application No. 2006-059963, filed Mar. 6, 2006, the contents of which are incorporated herein by reference.

### BACKGROUND

1. Technical Field

This invention relates to a semiconductor device, a manufacturing method for a semiconductor device, and an electronic equipment.

2. Related Art

Portable telephone sets, notebook-type personal computers, PDAs (Personal Data Assistants), and other portable electronic equipment are required to be compact and lightweight.

This has been accompanied by the problem of achieving higher semiconductor chip packaging densities, as the packaging space for semiconductor chips in portable electronic equipment has become extremely limited.

As a result, there have been proposals of three-dimensional packaging technologies for semiconductor chips.

FIGS. 9A and 9B are cross-sectional views of a semiconductor device of the prior art.

As disclosed in Japanese Unexamined Patent Application, First Publication No. 2003-46057, in three-dimensional packaging technology, a plurality of semiconductor chips 2 and 3 are stacked and positioned, the semiconductor chips 2 and 3 are caused to be electrically continuous via a penetrating electrode 34, and by connecting the semiconductor chips 2 and 3, a high semiconductor chip packaging density is realized.

In order to protect the circuit or the like formed by semiconductor chips, a sealing resin 80 is placed between the stacked semiconductor chips 2 and 3.

If the resin is formed so as to cover the entirety, including the side surface 52 of the semiconductor chip 2 and the side surface 53 of the semiconductor chip 3, the external dimensions of the semiconductor device are increased.

Hence, technology has been developed in which, by filling only the space between the semiconductor chips 2 and 3 with the sealing resin 80, a packaging structure is realized while retaining the size of the semiconductor chips.

However, as shown in FIG. 9A, if the amount of the sealing resin 80 used in filling is large, the end portion 81 of the sealing resin 80 protrudes on the outside of the side surface 52 of the semiconductor chip 2 and the side surface 53 of the semiconductor chip 3.

If high-temperature and high-humidity cycle tests are performed with this structure unmodified, then expansion and contraction of the sealing resin 80 is repeated at the interface 82 between the semiconductor chip 2 and the sealing resin 80 and at the interface 83 between the semiconductor chip 3 and the sealing resin 80, and there is the possibility that the sealing resin 80 may be detached.

In addition, as shown in FIG. 9B, if the amount of the sealing resin 80 used in filling is small, the end portion 81 of the sealing resin 80 may be depressed to further inside than the side surface 52 of the semiconductor chip 2 and the side surface 53 of the semiconductor chip 3.

If high-temperature and high-humidity cycle tests are performed with this structure unmodified, then there is the possibility of detachment of the sealing resin 80 at the interface 82 between the semiconductor chip 2 and the sealing resin 80 and at the interface 83 between the semiconductor chip 3 and the sealing resin 80.

### SUMMARY

An advantage of some aspects of the invention is to provide a semiconductor device and a manufacturing method for a semiconductor device, which can prevent detachment of sealing resin, and to provide an electronic equipment which can realize excellent reliability.

A first aspect of the invention provides a semiconductor device including: a plurality of stacked semiconductor chips including a first semiconductor chip having a side surface, and a second semiconductor chip stacked on the first semiconductor chip; and a sealing resin placed between the plurality of semiconductor chips, at least one edge of the first semiconductor chip is positioned on an inner side of the second semiconductor chip, and the sealing resin placed between the first semiconductor chip and the second semiconductor chip is extended over the side surface of the first semiconductor chip.

It is preferable that the semiconductor device of the first aspect of the invention further include: a penetrating electrode formed in each of the plurality of semiconductor chips, the plurality of semiconductor chips be stacked each other and be interconnected each other via the penetrating electrodes.

According to this configuration, the area of the side surface of the first semiconductor chip covered by the sealing resin can be increased. As a result, it is possible to reliably adhere closely the first semiconductor chip and the sealing resin, and it is possible to prevent detachment of the sealing resin.

A second aspect of the invention provides a semiconductor device including: a plurality of stacked semiconductor chips including a first semiconductor chip having a first surface and a side surface, and a second semiconductor chip stacked on the first chip and having a second surface facing to the first surface; and a sealing resin placed between the plurality of semiconductor chips, a peripheral portion of the first surface of the first semiconductor chip is position on an inner side of a peripheral portion of the second surface of the second semiconductor chip, and the sealing resin placed between the first semiconductor chip and the second semiconductor chip is extended over the side surface of the first semiconductor chip.

It is preferable that the semiconductor device of the second aspect of the invention further include: a penetrating electrode formed in each of the plurality of semiconductor chips, the plurality of semiconductor chips be stacked each other and be interconnected each other via the penetrating electrodes.

According to this configuration, substantially the entirety of the first semiconductor chip is covered with the sealing resin. As a result, when the semiconductor device is subjected to high-temperature and high-humidity cycle tests, expansion and contraction of the sealing resin is limited by the first semiconductor chip.

Hence, it is possible to reliably adhere closely the semiconductor chips and the sealing resin, and it is possible to prevent detachment of the sealing resin.

It is preferable that the semiconductor device of the second aspect of the invention further include: a substrate having a packaging surface on which the plurality of semiconductor chips are packaged, the first semiconductor chip and the second semiconductor chip be stacked in order in the perpendicular direction of the packaging surface, and the peripheral portion of the first surface of the first semiconductor chip be positioned on the inner side of the peripheral portion of the second surface of the second semiconductor chip.

According to this configuration, substantially the entirety of the plurality of semiconductor chips is covered with the sealing resin. As a result, it is possible to prevent detachment of the sealing resin from the plurality of semiconductor chips.

It is preferable that, in the semiconductor device of the second aspect of the invention, the side surface of the first semiconductor chip be positioned on the inner side from the peripheral portion of the second surface of the second semiconductor chip.

It is preferable that the semiconductor device of the second aspect of the invention further include: an inclined surface formed on the side surface of the first semiconductor chip.

According to this configuration, the peripheral portion of the first semiconductor chip is positioned on the inner side of the peripheral portion of the second surface of the second semiconductor chip.

As a result, substantially the entirety of the first semiconductor chip is covered with sealing resin. Expansion and contraction of the sealing resin is limited by the first semiconductor chip.

Hence, it is possible to prevent detachment of the sealing resin.

It is preferable that the semiconductor device of the second aspect of the invention further include: a chamfer portion formed on the side surface of the first semiconductor chip.

It is preferable that the semiconductor device of the second aspect of the invention further include: a rounded surface formed on the side surface of the first semiconductor chip.

According to this configuration, the area of the side surface of the first semiconductor chip covered by the sealing resin can be increased. As a result, it is possible to reliably adhere closely the first semiconductor chip and the sealing resin, and expansion and contraction of the sealing resin is limited by the first semiconductor chip.

Hence, it is possible to prevent detachment of the sealing resin.

A third aspect of the invention provides a manufacturing method for a semiconductor device, including: preparing a plurality of semiconductor chips including a first semiconductor chip having a first surface and a side surface, and a second semiconductor chip having a second surface; applying a sealing resin to each of the plurality of semiconductor chips; stacking the plurality of semiconductor chips, by facing the first surface of the first semiconductor chip to the second surface of the second semiconductor chip and by stacking the first semiconductor chip and the second semiconductor chip; positioning a peripheral portion of the first surface of the first semiconductor chip on an inner side of a peripheral portion of the second surface of the second semiconductor chip; and extending the sealing resin placed between the first semiconductor chip and the second semiconductor chip over the side surface of the first semiconductor chip.

According to this configuration, it is possible to stabilize the amount of liquid sealing resin applied, and it is possible to stabilize the shape of the end portion of the sealing resin after the sealing resin is cured.

Hence, substantially the entirety of the first semiconductor chip can be covered by the sealing resin, and it is possible to prevent detachment of sealing resin.

A fourth aspect of the invention provides a manufacturing method for a semiconductor device, including: preparing a plurality of semiconductor chips including a first semiconductor chip having a first surface and a side surface, and a second semiconductor chip having a second surface; stacking the plurality of semiconductor chips, so that the peripheral portion of the first surface of the first semiconductor chip is positioned on the inner side of the peripheral portion of the second surface of the second semiconductor chip, while facing the first surface of the first semiconductor chip to the second surface of the second semiconductor chip; extending the sealing resin placed between the first semiconductor chip and the second semiconductor chip over the side surface of the first semiconductor chip, by injecting liquid sealing resin into the spaces between the plurality of semiconductor chips.

According to this configuration, since the process of stacking semiconductor chips and the process of injecting the liquid sealing resin are performed separately, it is possible to prevent intrusion of the sealing resin into the connection portions of the penetrating electrodes between adjacent semiconductor chips.

Hence, it is possible to secure reliability of the electrical connections between the plurality of semiconductor chips.

A fifth aspect of the invention provides an electronic equipment including the above-described semiconductor device.

According to this configuration, a semiconductor device in which detachment of sealing resin is prevented is included, so that electronic equipment with excellent reliability can be provided.

### BRIEF DESCRIPTION OF THE DRAWINGS

FIG. 1 is a cross-sectional view of the semiconductor device of a first embodiment.

FIG. 2A is a cross-sectional view that shows the semiconductor device of the first embodiment, and is an enlarged view of portion A in FIG. 1, FIG. 2B is a cross-sectional view that shows the semiconductor device of a second embodiment, and is an enlarged view of portion A in FIG. 1.

FIG. 3A is a cross-sectional view that shows the semiconductor device of a third embodiment, and FIG. 3B is a cross-sectional view that shows the semiconductor device of a fourth embodiment.

FIG. 4 is a cross-sectional view that shows the semiconductor device of a fifth embodiment.

FIG. 5 is a cross-sectional view that shows the semiconductor device of a sixth embodiment.

FIG. 6 is a cross-sectional view that shows a semiconductor chip.

FIGS. 7A and 7B are views that explain a relocated wiring of semiconductor chips.

FIG. 8 is a perspective view of a portable telephone.

FIGS. 9A and 9B are cross-sectional views that show a semiconductor device of the prior art.

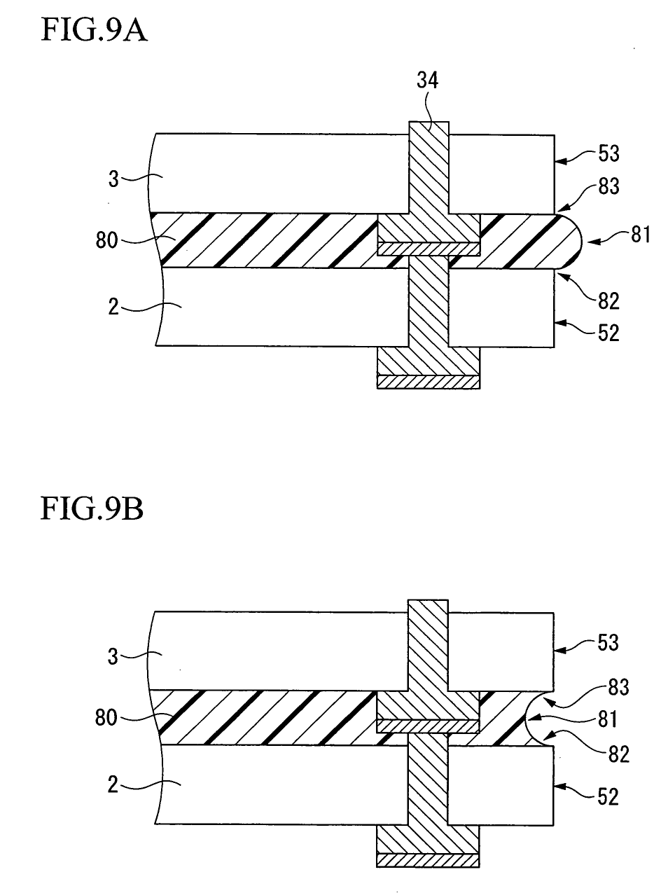

### DESCRIPTION OF EXEMPLARY EMBODIMENTS

Below, embodiments of the invention are explained, referring to the drawings.

In each of the drawings used in the following explanations, the scales of members are modified appropriately to sizes enabling recognition of the members.

### First Embodiment

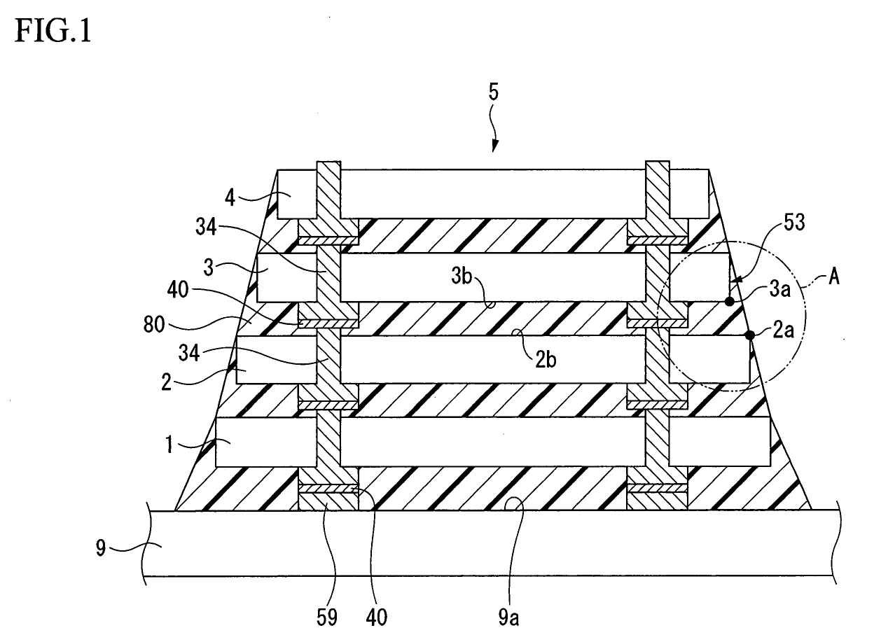

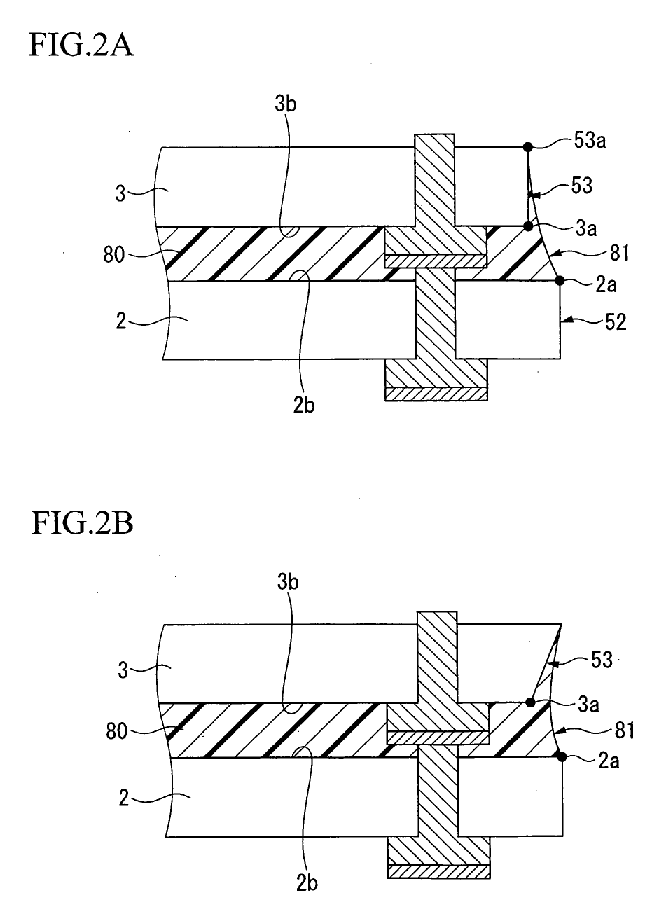

First, the semiconductor device of a first embodiment of the invention is explained, referring to FIG. 1 and FIG. 2A.

FIG. 1 is a cross-sectional view of the semiconductor device of the first embodiment.

The semiconductor device 5 of the first embodiment includes a plurality of stacked semiconductor chips 1, 2, 3, and 4.

The plurality of semiconductor chips 1, 2, 3, and 4 are positioned on the packaging surface 9a of a circuit substrate 9 (substrate).

The external sizes of the plurality of semiconductor chips 1, 2, 3, and 4 become successively smaller in moving from the packaging surface 9a of the circuit substrate 9 in the perpendicular direction.

As shown in FIG. 1, the upper-side semiconductor chip 3 (first semiconductor chip) having a first surface 3b and the lower-side semiconductor chip 2 (second semiconductor chip) having a second surface 2b are mutually faced.

Here, the first surface 3b of the upper-side semiconductor chip 3 is faced to the second surface 2b of the lower-side semiconductor chip 2.

The side surface 53 including the peripheral portion 3a of the first surface 3b, of the upper-side semiconductor chip 3 is positioned on the inner side of the peripheral portion 2a of the second surface 2b of the lower-side semiconductor chip 2.

Each of the semiconductor chips 1, 2, 3, and 4 is a semiconductor substrate made of Si (silicon) or the like.

Moreover, integrated circuits (not shown) including transistors, memory elements, and other electronic elements, are formed on the active surfaces of the semiconductor substrates.

In each of the semiconductor chips 1, 2, 3, and 4, has penetrating electrodes 34.

In each of the semiconductor chips 1, 2, 3, and 4, the penetrating electrode 34 is extended from the active surface to the rear surface of the semiconductor substrate.

The detailed configuration and manufacturing method for the penetrating electrodes 34 are explained below.

The above-described semiconductor chips 1, 2, 3, and 4 are stacked on the packaging surface 9a of the circuit substrate 9.

Specifically, each of the penetrating electrodes 34 of the semiconductor chips 1, 2, 3, and 4 are interconnected to realize electrical continuity via a solder layer 40.

For this reason, the penetrating electrodes 34 in the semiconductor chips 1, 2, 3, and 4 are formed in the same positions.

In other words, as seen from the direction perpendicular to the packaging surface 9a of the circuit substrate 9, each of the penetrating electrodes 34 of the semiconductor chips 1, 2, 3, and 4 are positioned so as to overlap.

In FIG. 1, four semiconductor chips are stacked, but the number of chips stacks is not limited to four.

Sealing resin 80 is placed between the semiconductor chips.

The sealing resin 80 protects the integrated circuits formed on the active surfaces of the semiconductor chips 1, 2, 3, and 4.

The material of this sealing resin 80 is material the main component of which is an epoxy or other thermo-curable resin.

The thermo-curable resin which is the main component may be dispersed in a filler of silica or the like.

When the amount of filler dispersed is adjusted to bring the thermal expansion coefficient of the sealing resin 80 close to the thermal expansion coefficient of the semiconductor chips, the amount of expansion and contraction of the sealing resin 80 relative to the semiconductor chips is reduced, and so detachment of sealing resin 80 can be suppressed.

Next, a forming method for the stacked member including the semiconductor chips 1, 2, 3, and 4 and sealing resin 80 is explained.

First, all the semiconductor chips 1, 2, 3, and 4 are stacked, and are positioned on the packaging surface 9a of the circuit substrate 9.

At this time, the solder layer 40 is heated to the temperature greater than or equal to the melting temperature. Upper and lower penetrating electrodes 34 are connected so as to be electrically continuous.

Next, liquid sealing resin is injected from a side of the semiconductor chips toward the spaces between semiconductor chips 1, 2, 3, and 4.

Specifically, the stacked member of semiconductor chips 1, 2, 3, and 4 is placed within a vacuum chamber, and an inner space of the vacuum chamber is decompressed. Then, sealing resin is applied to the entire side surface of the stacked member. At this time, the spaces between the stacked chips are maintained at negative pressure.

Next, by removing the stacked member from the vacuum chamber, a pressure difference occurs between the atmosphere and the spaces between the semiconductor chips 1, 2, 3, and 4, and the sealing resin is injected into the spaces between the semiconductor chips 1, 2, 3, and 4.

When applying the sealing resin, it is preferable that the sealing resin be heated until just before the curing-temperature, to enhance fluidity.

By this means, sealing resin can be filled without gaps between the spaces between the semiconductor chips 1, 2, 3, and 4, and the time for filling can be shortened.

Finally, when the sealing resin is heated to the temperature greater than or equal to the melting temperature to cure, the spaces between the semiconductor chips 1, 2, 3, and 4 are sealed by the sealing resin 80.

In the above-described method, the process of stacking the semiconductor chips 1, 2, 3, and 4 and the process of injecting sealing resin 80 are performed separately, so that sealing resin 80 does not intrude in the connection portions of the penetrating electrodes 34 of each of the semiconductor chips 1, 2, 3, and 4.

Hence, electrical connections between semiconductor chips 1, 2, 3, and 4 can be reliably secured.

As the forming method for the above-described stacked member, the following method can also be adopted.

First, a liquid drop dispensing method or the like is used to apply liquid sealing resin to the surfaces of each of the semiconductor chips 1, 2, 3, and 4.

Next, the semiconductor chips 1, 2, 3, and 4 are stacked, and are positioned on the packaging surface 9a of the circuit substrate 9.

Next, the semiconductor device 5 is heated, and adjacent penetrating electrodes 34 are connected and caused to be electrically continuous, while also filling the spaces between semiconductor chips 1, 2, 3, and 4 with sealing resin 80.

The temperature to which the semiconductor device 5 is heated at this time is set to equal to or greater than the melting temperature of the solder layer 40, and equal to or less than the curing-temperature of the sealing resin 80.

Finally, by heating the sealing resin 80 to equal to or greater than the curing-temperature and curing the resin, the spaces between the semiconductor chips 1, 2, 3, and 4 are sealed by the sealing resin 80.

Through the above-described method, a liquid drop dispensing method can be employed as the applying method for the liquid sealing resin 80, so that the sealing resin 80 can be applied in prescribed amounts at prescribed positions.

As a result, the shape of the end surfaces of the sealing resin 80 can be stabilized.

An anisotropic conductive film or the like may be placed on the surfaces of the semiconductor chips.

The stacked semiconductor chips are then packaged on the circuit substrate 9.

This circuit substrate 9 is a glass epoxy substrate or other organic substrate, on the surface of which a wiring pattern (not shown) forming the desired circuit and terminals 59 for connection with external devices are formed.

The penetrating electrodes 34 of the semiconductor chip 1 in the lowermost layer are packaged, via the solder layer 40, onto the connection terminals 59 of the circuit substrate 9.

Moreover, the sealing resin 80 is also placed between the semiconductor chip 1 and the circuit substrate 9.

Shape of End Faces of Sealing Resin

In the first embodiment, the external sizes of the stacked semiconductor chips 1, 2, 3, and 4 become successively smaller in moving in the perpendicular direction from the packaging surface 9a of the circuit substrate 9.

Below is explained an example of a pair of adjacent semiconductor chips which are a second semiconductor chip 2, positioned second from the circuit substrate 9, and a first semiconductor chip 3, positioned third from the substrate, however the case is similar for other adjacent semiconductor chips.

FIG. 2A is an enlarged view of portion A in FIG. 1.

As shown in FIG. 2A, the side surface 53 including the peripheral portion 3a of the first surface 3b of the upper-side semiconductor chip (first semiconductor chip) 3 is positioned on the inner side of the peripheral portion 2a of the second surface 2b of the lower-side semiconductor chip (second semiconductor chip) 2.

For example, the side surface 53 of the upper-side semiconductor chip 3 is positioned approximately 20 μm on the inner side of the side surface 52 of the lower-side semiconductor chip 2.

In a case in which the upper-side semiconductor chip 3 and lower-side semiconductor chip 2 are semiconductor chips of different types, the smaller-size semiconductor chip is employed as the upper-side semiconductor chip, and the larger-size semiconductor chip is employed as the lower-side semiconductor chip.

In a case in which the electrode positions of the upper-side semiconductor chip 3 and lower-side semiconductor chip 2 are different, the relocated wiring technique described below may be used to relocate the electrodes.

Furthermore, in a case in which the upper-side semiconductor chip 3 and lower-side semiconductor chip 2 are semiconductor chips of the same type, by shifting the dicing position when cutting the wafer to obtain individual semiconductor chips, semiconductor chips of different sizes may be formed.

Because the width of the dicing street in the wafer is approximately 100 μm, merely by shifting the dicing position, the desired semiconductor chips with different sizes can be formed.

When the spaces between the plurality of semiconductor chips of different sizes are filled with the liquid sealing resin, the end portion 81 of the sealing resin 80 wets the side surface 53 of the upper-side semiconductor chip 3 of smaller size, as shown in FIG. 2A.

In addition, the end portion 81 of the sealing resin 80 is formed into a fillet shape (arc shape) from the peripheral portion 2a of the second surface 2b of the lower-side semiconductor chip 2, to the upper end portion 53a of the side surface 53 of the upper-side semiconductor chip 3.

The above-described end portion 81 can be formed merely by filling the spaces between semiconductor chips with liquid sealing resin 80, without applying any special treatment.

When the sealing resin 80 is cured, the end portion 81 of the sealing resin 80 placed between the pair of semiconductor chips 2 and 3 is formed extending over the side surface 53 of the smaller-size upper-side semiconductor chip 3.

In this way, in a semiconductor device of the first embodiment, the side surface 53 including the peripheral portion 3a of the first surface 3b of the upper-side semiconductor chip 3 is positioned on the inner side of the peripheral portion 2a of the second surface 2b of the lower-side semiconductor chip 2, and the end portion 81 of the sealing resin 80 placed between the pair of semiconductor chips 2 and 3 is extended over the side surface 53 of the upper-side semiconductor chip 3.

By means of this configuration, substantially the entirety of the upper-side semiconductor chip 3 is covered with the sealing resin 80.

In this configuration, when high-temperature and high-humidity cycle tests are performed, expansion and contraction of the sealing resin 80 is limited by the upper-side semiconductor chip 3.

Hence, it is possible to reliably adhere closely the semiconductor chips and sealing resin 80, and detachment of the sealing resin 80 can be prevented.

If the side surface 53 of the upper-side semiconductor chip 3 is coarsened in advance, detachment of the resin can be more reliably prevented through an anchor effect.

Furthermore, if at least one edge of the upper semiconductor chip 3 is positioned on the inner side of the lower-side semiconductor chip 2, then the end portion 81 of the sealing resin 80 can be extended at least over the side surface 53 including the edge of the upper-side semiconductor chip 3.

In this case also, the area of the side surface 53 of the upper-side semiconductor chip 3 covered by the sealing resin 80 can be increased. By this means, it is possible to reliably adhere closely the upper-side semiconductor chip 3 and the sealing resin 80, and detachment of the sealing resin 80 can be prevented.

If the entirety of the stacked semiconductor chips is embedded in the sealing resin 80, detachment of the sealing resin 80 can be prevented, but the external dimensions of the semiconductor device 5 become large.

In contrast, by means of the first embodiment, the sizes of the semiconductor chips can be maintained in realizing a packaged structure, and detachment of the sealing resin 80 can be prevented.

In addition, in the semiconductor device 5 shown in FIG. 1, the external sizes of each of the stacked semiconductor chips 1, 2, 3, and 4 are successively smaller in moving in the perpendicular direction away from the packaging surface 9a of the circuit substrate 9.

That is, the peripheral portion 3a of the first surface 3b of the semiconductor chip 3 positioned furthest from the circuit substrate 9 is positioned on the inner side of the peripheral portion 2a of the second surface 2b of the semiconductor chip 2 positioned closer to the circuit substrate 9.

By this means, substantially the entirety of all of the semiconductor chips 1, 2, 3, and 4 is covered with sealing resin 80, and detachment of sealing resin 80 is prevented for all of the semiconductor chips 1, 2, 3, and 4.

Among the stacked semiconductor chips, if for any pair of semiconductor chips the peripheral portion of the upper-side semiconductor chip is positioned on the inner side of the peripheral portion of the lower-side semiconductor chip, then detachment of the sealing resin 80 can be prevented at least on the side surface of the upper-side semiconductor chip.

### Second Embodiment

Next, the semiconductor device of a second embodiment of the invention is explained, referring to FIG. 2B.

FIG. 2B is a cross-sectional view of the semiconductor device of the second embodiment.

In the second embodiment, the size of the upper-side semiconductor chip 3 is equal to that of the lower-side semiconductor chip 2, but an inclined surface is formed on the side surface 53 of the upper-side semiconductor chip 3.

This inclined surface can be formed by anisotropic etching of the silicon substrate.

By forming this inclined surface, the peripheral portion 3a of the first surface 3b of the upper-side semiconductor chip 3 is positioned on the inner side of the peripheral portion 2a of the second surface 2b of the lower-side semiconductor chip 2.

Even when liquid sealing resin 80 is filled into the spaces between these semiconductor chips 2 and 3, the end portion 81 of the sealing resin 80 wets the side surface 53 of the upper-side semiconductor chip 3.

When this sealing resin 80 is cured, the end portion 81 of the sealing resin 80 placed between the pair of semiconductor chips is extended over the side surface 53 of the upper-side semiconductor chip 3.

That is, the sealing resin 80 covers substantially the entirety of the upper-side semiconductor chip 3, so that similarly to the first embodiment, detachment of the sealing resin 80 can be prevented.

### Third Embodiment

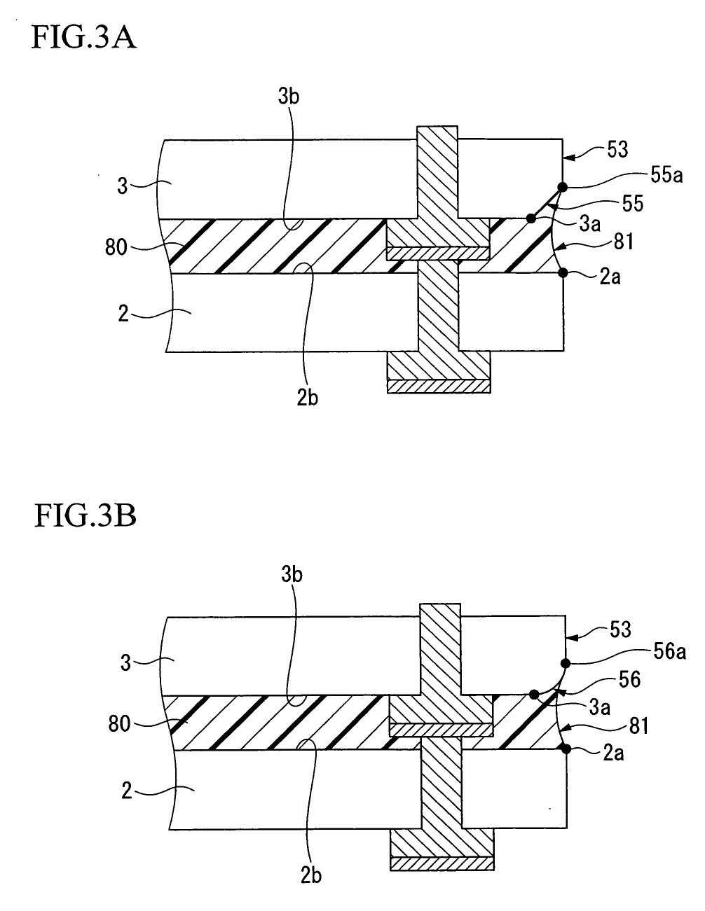

Next, the semiconductor device of a third embodiment of the invention is explained, referring to FIG. 3A.

FIG. 3A is a cross-sectional view of the semiconductor device of the third embodiment.

In the third embodiment also, the size of the upper-side semiconductor chip 3 is equal to that of the lower-side semiconductor chip 2.

However, in the third embodiment, a chamfer portion 55 is formed in the peripheral portion 3a of the first surface 3b of the upper-side semiconductor chip 3, as shown in FIG. 3A.

By this means, the peripheral portion 3a of the first surface 3b of the upper-side semiconductor chip 3 is positioned on the inner side of the peripheral portion 2a of the second surface 2b of the lower-side semiconductor chip 2.

When liquid sealing resin 80 is filled into the space between the semiconductor chips 2 and 3, the end portion 81 of the sealing resin 80 wets the side surface 53 of the upper-side semiconductor chip 3 up to the upper end portion 55a of the chamfer portion 55.

When the sealing resin 80 is cured, the end portion 81 of the sealing resin 80 placed in the space between the pair of semiconductor chips 2 and 3 is extended over the side surface 53 of the upper-side semiconductor chip 3.

By this means, the area of the side surface 53 of the upper-side semiconductor chip 3 covered with sealing resin 80 is increased, so that expansion and contraction of the sealing resin 80 is suppressed by the upper-side semiconductor chip 3.

Hence, detachment of the sealing resin 80 can be prevented.

### Fourth Embodiment

Next, the semiconductor device of a fourth embodiment of the invention is explained, referring to FIG. 3B.

FIG. 3B is a cross-sectional view of the semiconductor device of the fourth embodiment.

In the fourth embodiment also, the size of the upper-side semiconductor chip 3 is equal to that of the lower-side semiconductor chip 2.

However, in the fourth embodiment shown in FIG. 3B, a rounded surface 56 is formed on the peripheral portion 3a of the first surface 3b of the upper-side semiconductor chip 3.

By this means, the peripheral portion 3a of the first surface 3b of the upper-side semiconductor chip 3 is positioned on the inner side of the peripheral portion 2a of the second surface 2b of the lower-side semiconductor chip 2.

When the liquid sealing resin 80 is supplied into the space between these semiconductor chips 2 and 3, the end portion 81 of the sealing resin 80 wets the side surface 53 of the upper-side semiconductor chip 3 up to the upper end portion 56a of the rounded surface 56.

When the sealing resin 80 is cured, the end portion 81 of the sealing resin 80 placed in the space between the pair of semiconductor chips 2 and 3 is extended over the side surface 53 of the upper-side semiconductor chip 3.

By this means, the area of the side surface 53 of the upper-side semiconductor chip 3 covered by the sealing resin 80 is increased, so that expansion and contraction of the sealing resin 80 is suppressed by the upper-side semiconductor chip 3.

Hence, detachment of the sealing resin 80 can be prevented.

### Fifth Embodiment

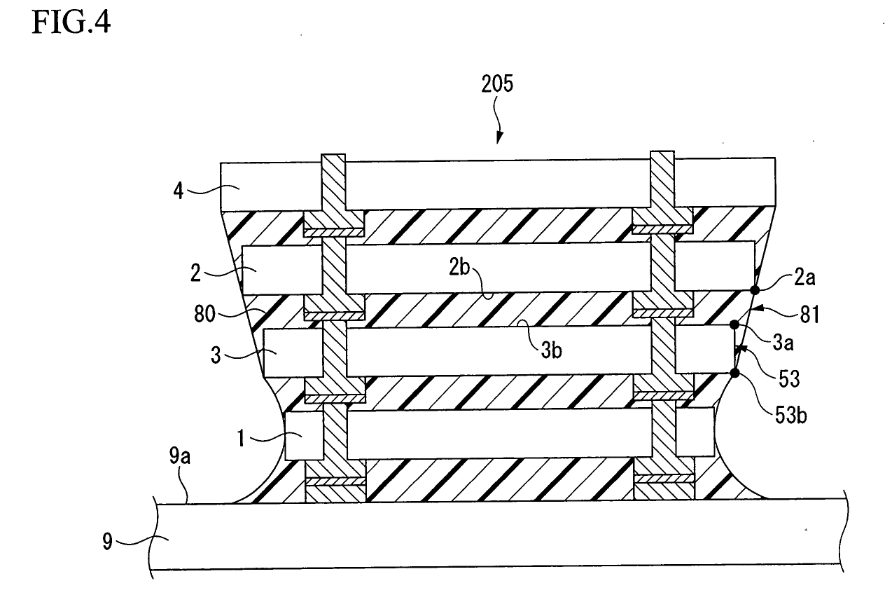

Next, the semiconductor device-of a fifth embodiment is explained, using FIG. 4.

FIG. 4 is a cross-sectional view of the semiconductor device of the fifth embodiment.

The semiconductor device 205 of the fifth embodiment differs from that of the first embodiment in that the external sizes of the stacked semiconductor chips 1, 2, 3, and 4 increase in succession in the perpendicular direction from the packaging surface 9a of the circuit substrate 9.

In the following explanation, the first semiconductor chip 3 positioned second from the circuit substrate 9 and the second semiconductor chip 2 positioned third from the circuit substrate 9 are used as an example of a pair of adjacent semiconductor chips.

Furthermore, detailed explanations of portions which are configured similarly to the first embodiment are omitted.

In the semiconductor device 205 of the fifth embodiment, the side surface 53 including the peripheral portion 3a of the first surface 3b of the lower-side semiconductor chip (first semiconductor chip) 3 is positioned on the inner side of the peripheral portion 2a of the second surface 2b of the upper-side semiconductor chip (second semiconductor chip) 2.

When liquid sealing resin is filled between these semiconductor chips, the end portion 81 of the sealing resin 80 wets and expands over the side surface 53 of the lower-side semiconductor chip 3 of size smaller than the upper-side semiconductor chip 2.

In addition, the end portion 81 of the sealing resin 80 is formed into a fillet shape from the peripheral portion 2a of the second surface 2b of the upper-side semiconductor chip 2, to the lower end portion 53a of the side surface 53 of the lower-side semiconductor chip 3.

When the sealing resin 80 is cured, the end portion 81 of the sealing resin 80 placed between the pair of semiconductor chips 2 and 3 is extended over the side surface 53 of the smaller-size lower-side semiconductor chip 3.

That is, substantially the entirety of the lower-side semiconductor chip 3 is covered with the sealing resin 80.

In this configuration, when high-temperature and high-humidity cycle tests are performed, expansion and contraction of the sealing resin 80 is limited by the lower-side semiconductor chip 3.

Hence, detachment of the sealing resin 80 can be prevented.

If at least one edge of the lower-side semiconductor chip 3 is positioned on the inner side of the upper-side semiconductor chip 2, then the end portion 81 of the sealing resin 80 can be extended at least over the side surface 53 including the edge of the lower-side semiconductor chip 3.

In this case also, the area of the side surface 53 of the lower-side semiconductor chip 3 which is covered by the sealing resin 80 can be increased. By this means, it is possible to reliably adhere closely the lower-side semiconductor chip 3 and sealing resin 80, and detachment of the sealing resin 80 can be prevented.

In addition, in the semiconductor device 205 of the fifth embodiment, the external sizes of the stacked semiconductor chips increase in succession in the perpendicular direction from the packaging surface 9a of the circuit substrate 9, so that detachment of the sealing resin 80 can be prevented for substantially all of the semiconductor chips in the semiconductor device 205.

Of the stacked semiconductor chips, if the peripheral portion of a lower-side semiconductor chip is positioned on the inner side of the peripheral portion of the upper-side semiconductor chip for all adjacent semiconductor chips, then detachment of sealing resin can be prevented at least for the lower-side semiconductor chip.

In the semiconductor device 205 of the fifth embodiment, similarly to the second embodiment, an inclined surface may be formed on the side surface 53 of the lower-side semiconductor chip 3. By this means, the peripheral portion 3a of the first surface 3b of the lower-side semiconductor chip 3 is positioned on the inner side of the peripheral portion 2a of the second surface 2b of the upper-side semiconductor chip 2.

Hence, advantageous results similar to those of the second embodiment are obtained, and detachment of sealing resin 80 can be prevented.

Similarly to the third embodiment and fourth embodiment, a chamfer portion 55, or a rounded surface 56, may be formed in the peripheral portion 3a of the first surface 3b of the lower-side semiconductor chip 3. By this means, the peripheral portion 3a of the first surface 3b of the lower-side semiconductor chip 3 is positioned on the inner side of the peripheral portion 2a of the second surface 2b of the upper-side semiconductor chip 2.

Hence, advantageous results similar to those of the third embodiment and fourth embodiment are obtained, and detachment of sealing resin 80 can be prevented.

### Sixth Embodiment

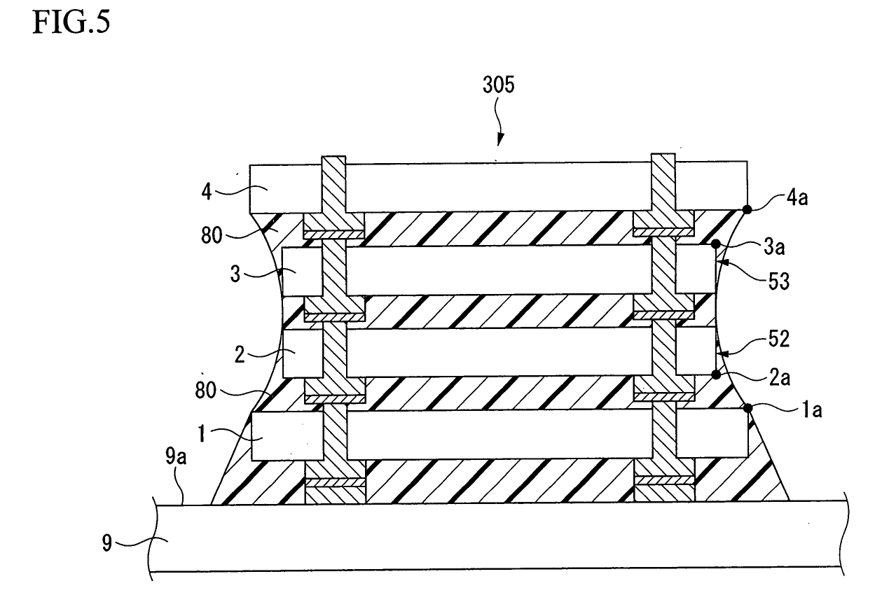

Next, the semiconductor device of a sixth embodiment is explained using FIG. 5.

FIG. 5 is a cross-sectional view of the semiconductor device of the sixth embodiment.

The semiconductor device 305 of the sixth embodiment differs from that of the first embodiment and fifth embodiment in that the external sizes of the stacked semiconductor chips 1, 2, 3, and 4 are smaller in the center layer portion, and larger in the upper layer portion and lower layer portion.

Detailed explanations of portions configured similarly to the first embodiment and fifth embodiment are omitted.

In the sixth embodiment, with respect to the semiconductor chip 1 positioned first from the packaging surface 9a of the circuit substrate 9 and the semiconductor chip 2 positioned second from the circuit substrate 9, the side surface 52 including the peripheral portion 2a of the upper-side semiconductor chip (first semiconductor chip) 2 is positioned on the inner side from the peripheral portion 1a of the lower-side semiconductor chip (second semiconductor chip) 1.

It is sufficient that at least one edge of the upper-side semiconductor chip 2 be positioned on the inner side of the lower-side semiconductor chip 1.

Hence, similarly to the first embodiment, detachment of the sealing resin 80 at the upper-side semiconductor chip 2 can be prevented.

With respect to the semiconductor chip 3 positioned third from the packaging surface 9a of the circuit substrate 9 and the semiconductor chip 4 positioned fourth from the circuit substrate 9, the side surface 53 including the peripheral portion 3a of the lower-side semiconductor chip (first semiconductor chip) 3 is positioned on the inner side of the peripheral portion 4a of the upper-side semiconductor chip (second semiconductor chip) 4.

It is sufficient that at least one edge of the lower-side semiconductor chip 3 be positioned on the inner side of the upper-side semiconductor chip 4.

Hence, similarly to the fifth embodiment, detachment of the sealing resin 80 at the upper-side semiconductor chip 2 can be prevented.

### Semiconductor Chips

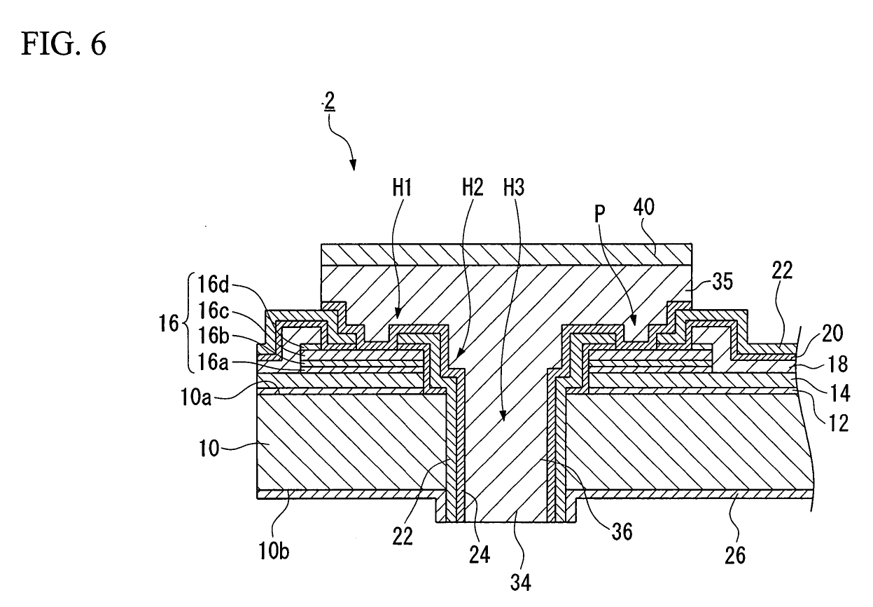

Next, the detailed configuration of the above-described semiconductor chips is explained using FIG. 6.

FIG. 6 is a cross-sectional view of a semiconductor chip.

The semiconductor chip 2 has a substrate 10 made of Si (silicon) or the like.

An integrated circuit (not shown) including transistors, memory elements, and other electronic elements are formed on the active surface 10a of the substrate 10.

An insulating film 12 made of SiO₂ (silicon oxide) or the like is formed on the active surface 10a.

An inter-layer insulating film 14 made of borophosphorosilicate glass (hereafter “BPSG”) or the like is formed on the surface of the insulating film 12.

On the surface of the inter-layer insulating film 14 are formed electrode pads 16.

The electrode pads 16 are electrically connected to the above-described integrated circuit, and are formed so as to be arranged along the peripheral edges of the semiconductor chip 2 as seen from the direction perpendicular to the semiconductor chip 2.

The electrode pads 16 are formed by layering, in order, a first layer 16a made of Ti (titanium) or the like, a second layer 16b made of TiN (titanium nitride) or the like, a third layer 16c made of AlCu (aluminum/copper) or the like, and a fourth layer (cap layer) 16d made of TiN or the like.

The constituent material of the electrode pads 16 may be modified appropriately according to the electrical characteristics, physical characteristics, and chemical characteristics required of the electrode pads 16.

That is, the electrode pads 16 may be formed using only the Al generally used as electrodes in integrated circuits, or the electrode pads 16 may be formed using only Cu, with low electrical resistance.

A passivation film 18 is formed on the surface of the inter-layer insulating film 14 so as to cover the electrode pads 16.

The passivation film 18 is made of SiO₂ (silicon oxide), SiN (silicon nitride), a polyimide resin or the like, and is formed to a thickness of for example approximately 1 μm.

In the center portion of each of the electrode pads 16 is formed an aperture portion H1, penetrating the passivation film 18 and the fourth layer 16d of the electrode pad 16.

On the inside of the aperture portion H1 is formed an aperture portion H2 penetrating the remainder of the electrode pad 16, the inter-layer insulating film 14, and the insulating film 12.

The diameter of the aperture portion H2 is for example set to approximately 60 μm.

An insulating film 20 made of SiO₂ (silicon oxide) or the like is formed on the surface of the passivation film 18 and on the inner surfaces of the aperture portion H1 and aperture portion H2.

The insulating film 20 functions as a mask when forming the penetrating hole H3, described next.

In the center portion of the electrode pad 16 is formed a penetrating hole H3 penetrating the substrate 10.

The penetrating hole H3 is formed with a diameter smaller than that of the aperture portion H2, of for example approximately 30 μm.

The shape of the penetrating hole H3 is not limited to a circular shape as seen when viewing the semiconductor chip 2 from the perpendicular direction, but may be rectangular.

An insulating film 22, which is a first insulating layer, is formed on the inner surface of the penetrating hole H3 and the surface of the insulating film 20.

The insulating film 22 prevents the occurrence of current leaks from the penetrating electrode 34 to the substrate 10 and similar

The insulating film 22 is made of SiO₂, SiN, or another electrically insulating material, and is formed to a thickness of approximately 1 μm.

Furthermore, the insulating film 22 is formed to protrude from the rear surface 10b of the substrate 10.

A portion of the insulating film 20 and insulating film 22 is removed in the portion P of the surface of the third layer 16c of the electrode pads 16.

A base film 24 is formed on the surface of the third layer 16c exposed at the portion P of the electrode pads 16, and on the surface of the remaining insulating film 22.

The base film 24 includes a barrier layer (barrier metal) formed on the surface of the insulating film 22 or the like, and a seed layer (seed electrode) formed on the surface of the barrier layer.

The barrier layer is provided to prevent diffusion into the substrate 10 of the constituent material of the penetrating electrode 34, described below.

The barrier layer is made of TiW (tantalum tungsten), TiN (titanium nitride), TaN (tantalum nitride), or the like.

The seed layer is an electrode when the penetrating electrode 34, described below, is formed by plating.

The seed layer is made of Cu, Au, Ag, or the like.

The penetrating electrode 34 is formed on the inside of the base film 24.

The penetrating electrode 34 is made of Cu, W, or another conductive material with low electrical resistance.

If the penetrating electrodes 34 are formed using poly-Si (polysilicon) doped with B, P, or other impurities as a conductive material, there is no need to prevent diffusion into the substrate 10, and the above-described barrier layer is unnecessary.

A plug portion 36 of the penetrating electrode 34 is formed in the penetrating hole H3.

The lower-end surface of the plug portion 36 is exposed to the outside.

Furthermore, a post portion 35 of the penetrating electrode 34 is formed above the electrode pad 16.

The post portion 35 need not be circular in plane view, but may be formed with a rectangular shape in plane view.

The post portion 35 and electrode pad 16 are electrically connected at the portion P via the base film 24.

A solder layer 40 is formed on the upper surface of the post portion 35 of the penetrating electrode 34.

The solder layer 40 may be formed from an ordinary PbSn alloy or the like, but from environmental considerations and the similar, formation using AgSn alloy or another lead-free solder material is preferable.

In place of the solder layer 40 of a soft solder material, a layer of a hard solder material (molten metal) made of an SnAg alloy or the like, or a layer of a metal paste such as Ag paste or the like, may be formed.

Due to environmental considerations, it is preferable that this hard solder layer or metal paste layer also be formed from a lead-free material.

On the other hand, an insulating film 26 which is a second insulating layer is formed on the rear surface 10b of the substrate 10.

The insulating film 26 is made of SiO₂ (silicon oxide), SiN (silicon nitride), or another inorganic material, or a PI (polyimide) or other organic material.

The insulating film 26 is formed over the entirety of the rear surface 10b of the substrate 10, excluding the lower-end surfaces of the plug portions 36 of penetrating electrodes 34.

The insulating film 26 may also be formed selectively only on the periphery of the tip portions of the penetrating electrodes 34 on the rear surface 10b of the substrate 10.

By forming the insulating film 26, when stacking the semiconductor chips, contact of the solder layer of the adjacent semiconductor chips with the rear surface 10b of the substrate 10 can be prevented.

By this means, short-circuitting of signal lines with ground can be prevented.

Furthermore, protrusions from the surface of the insulating film 26 are formed on the tip surfaces of the plug portions 36 of the penetrating electrodes 34 on the rear side of the substrate 10.

The protruding height of the plug portions 36 is for example approximately 1 m to 20 μm.

By this means, when stacking the semiconductor chips, intervals between the semiconductor chips can be secured, and so the sealing resin can easily be filled into the gaps of the semiconductor chips.

Furthermore, even when instead of filling the sealing resin or the like after stacking the sealing resin is applied to the rear surface 10b of the semiconductor chip 2 before stacking, sealing resin can be applied while avoiding the protruding plug portions 36, so that semiconductor chip wiring connections can be made reliably.

The semiconductor chips 2 of this embodiment are configured as described above.

Relocated Wiring

Next, relocated wiring is explained using FIG. 6.

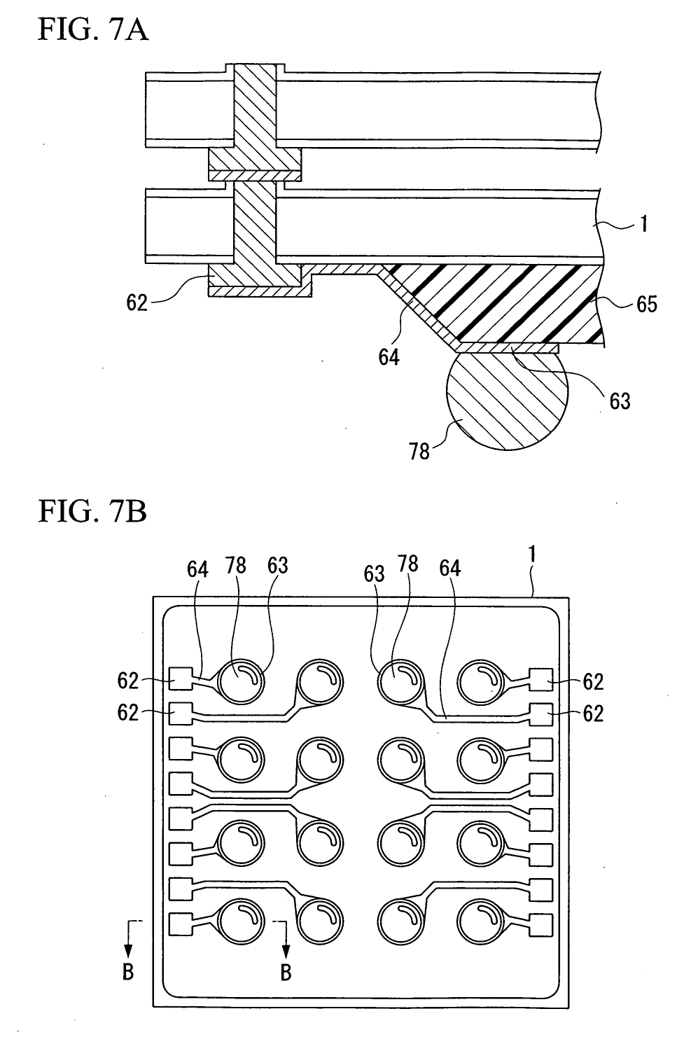

FIGS. 7A and 7B are views that explain relocated wiring of a semiconductor chip, FIG. 7A is a cross-sectional view taken along the line B-B in FIG. 7B, and FIG. 7B is a bottom view of a semiconductor chip 1.

As shown in FIG. 7B, a plurality of electrodes 62 are formed along peripheral portions of the bottom surface of the semiconductor chip 1.

Due to the reduced sizes of semiconductor chips in recent years, the pitch between adjacent electrodes has become extremely small.

When such a semiconductor chip 1 is packaged on a circuit substrate, there is the possibility of short-circuitting across adjacent electrodes.

Hence, in order to broaden the pitch between electrodes, relocated wiring of electrodes 62 is performed.

Specifically, the plurality of electrode pads 63 are formed into a matrix arrangement in the center portion of the bottom surface of the semiconductor chip 1.

Wirings 64 drawn from electrodes 62 are connected to these electrode pads 63.

By this means, the narrow-pitch electrodes 62 can be drawn into the center portion, and the pitch is broadened.

As shown in FIG. 7A, solder resist 65 is formed in the center portion of the bottom surface of the semiconductor chip 1 in the lowermost layer, and the electrode pads 63 are formed on the surface thereof.

Bumps 78 are formed on the surfaces of the electrode pads 63.

The bumps 78 are for example solder bumps, and are formed by a printing method or the like.

The bumps 78 are packaged on the connection terminals of the circuit substrate by for example reflow or FCB (Flip-Chip Bonding).

The semiconductor chip 1 may also be packaged on the circuit substrate via an anisotropic conductive film.

Electronic Equipment

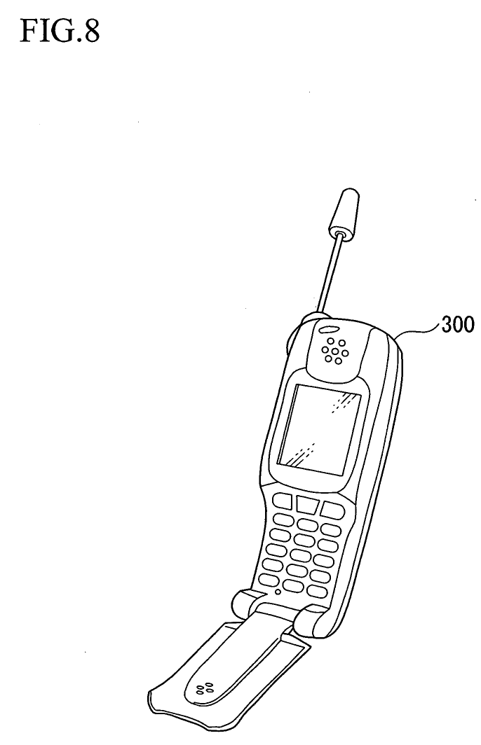

Next, an example of electronic equipment including the above-described semiconductor chips is explained using FIG. 8.

FIG. 8 is a perspective view of a portable telephone.

The above-described semiconductor chips are positioned within the housing of the portable telephone 300.

The above-described semiconductor chips can be applied in various electronic equipment other than the portable telephones.

For example, application is possible in such electronic equipment as liquid crystal projectors, personal computers (PCs) with multimedia support and engineering workstations (EWS), pagers, word processors, television sets, either viewfinder-type or direct-view camcorders, electronic organizers, electronic calculators, car navigation systems, POS terminals, devices equipped with touchscreens, and similar.

Electronic components can also be manufactured with the “semiconductor chips” in the above-described embodiments replaced with “electronic elements”.

As examples of electronic components manufactured using such electronic elements, for example, optical elements, resistors, capacitors, coils, oscillators, filters, temperature sensors, thermistors, varistors, potentiometers, and fuses.

The technical scope of this invention is not limited to the above-described embodiments, but includes various modifications to the above embodiments, without deviating from the gist of the invention.

That is, the specific materials, layer configurations and similar described in the embodiments are merely examples, and modifications can be made as appropriate.

What is claimed is:

1. A semiconductor device comprising:
a plurality of stacked semiconductor chips including a first semiconductor chip having a side surface, and a second semiconductor chip stacked on the first semiconductor chip; and
a sealing resin placed between the plurality of semiconductor chips, wherein at least one edge of the first semiconductor chip is positioned on an inner side of the second semiconductor chip, and the sealing resin placed between the first semiconductor chip and the second semiconductor chip is extended over the side surface of the first semiconductor chip.

2. The semiconductor device according to claim 1, further comprising:
a penetrating electrode formed in each of the plurality of semiconductor chips, wherein the plurality of semiconductor chips are stacked each other and are interconnected each other via the penetrating electrodes.

3. An electronic equipment comprising the semiconductor device according to claim 1.

4. A semiconductor device comprising:
a plurality of stacked semiconductor chips including a first semiconductor chip having a first surface and a side surface, and a second semiconductor chip stacked on the first chip and having a second surface facing to the first surface; and
a sealing resin placed between the plurality of semiconductor chips, wherein a peripheral portion of the first surface of the first semiconductor chip is position on an inner side of a peripheral portion of the second surface of the second semiconductor chip, and the sealing resin placed between the first semiconductor chip and the second semiconductor chip is extended over the side surface of the first semiconductor chip.

5. The semiconductor device according to claim 4, further comprising:
a penetrating electrode formed in each of the plurality of semiconductor chips, wherein the plurality of semiconductor chips are stacked each other and are interconnected each other via the penetrating electrodes.

6. The semiconductor device according to claim 4, further comprising:
a substrate having a packaging surface on which the plurality of semiconductor chips are packaged, wherein the first semiconductor chip and the second semiconductor chip are stacked in order in the perpendicular direction of the packaging surface, and the peripheral portion of the first surface of the first semiconductor chip is positioned on the inner side of the peripheral portion of the second surface of the second semiconductor chip.

7. The semiconductor device according to claim 4, wherein the side surface of the first semiconductor chip is positioned on the inner side from the peripheral portion of the second surface of the second semiconductor chip.

8. The semiconductor device according to claim 4, further comprising:
an inclined surface formed on the side surface of the first semiconductor chip.

9. The semiconductor device according to claim 4, further comprising:
a chamfer portion formed on the side surface of the first semiconductor chip.

10. The semiconductor device according to claim 4, further comprising:
a rounded surface formed on the side surface of the first semiconductor chip.

11. An electronic equipment comprising the semiconductor device according to claim 4.

12. A manufacturing method for a semiconductor device, comprising:
preparing a plurality of semiconductor chips including a first semiconductor chip having a first surface and a side surface, and a second semiconductor chip having a second surface;
applying a sealing resin to each of the plurality of semiconductor chips;
stacking the plurality of semiconductor chips, by facing the first surface of the first semiconductor chip to the second surface of the second semiconductor chip and by stacking the first semiconductor chip and the second semiconductor chip;
positioning a peripheral portion of the first surface of the first semiconductor chip on an inner side of a peripheral portion of the second surface of the second semiconductor chip; and
extending the sealing resin placed between the first semiconductor chip and the second semiconductor chip over the side surface of the first semiconductor chip.

13. A manufacturing method for a semiconductor device, comprising:
preparing a plurality of semiconductor chips including a first semiconductor chip having a first surface and a side surface, and a second semiconductor chip having a second surface;
stacking the plurality of semiconductor chips, so that the peripheral portion of the first surface of the first semiconductor chip is positioned on the inner side of the peripheral portion of the second surface of the second semiconductor chip, while facing the first surface of the first semiconductor chip to the second surface of the second semiconductor chip; and
extending the sealing resin placed between the first semiconductor chip and the second semiconductor chip over the side surface of the first semiconductor chip, by injecting liquid sealing resin into the spaces between the plurality of semiconductor chips.
